(19) United States
(12) Patent Application Publication
(10) Pub. No.: US 2022/0026329 A1
(43) Pub. Date: Jan. 27, 2022

(54) METHOD AND DEVICE FOR EVALUATING ATOMIZATION EFFICIENCY OF ELECTRIC ATOMIZER

(71) Applicant: BEIJING RESEARCH CENTER OF INTELLIGENT EQUIPMENT FOR AGRICULTURE, Beijing (CN)

(72) Inventors: Liping CHEN, Beijing (CN); Ruirui ZHANG, Beijing (CN); Qing TANG, Beijing (CN); Gang XU, Beijing (CN); Chenchen DING, Beijing (CN); Wen HUA, Beijing (CN)

(21) Appl. No.: 17/296,482

(22) PCT Filed: Sep. 14, 2020
(86) PCT No.: PCT/CN2020/115136

§ 371 Date: May 24, 2021

(30) Foreign Application Priority Data
Sep. 18, 2019 (CN) 201910882838.0

(51) Int. Cl. G01N 15/02; G01R 21/06; B05B 12/08

(52) U.S. Cl. CPC G01N 15/02; B05B 12/082; G01R 21/06

(57) ABSTRACT

A method and a device for evaluating atomization efficiency of an electric atomizer. The method includes: obtaining an idling power consumption according to an idling voltage and an idling current of an electric atomizer to be measured when idling; obtaining a working power consumption according to a working voltage and a working current of the electric atomizer when liquid pesticide flows into the electric atomizer; obtaining atomization parameters after the electric atomizer atomizes the liquid pesticide; and calculating the atomization efficiency of the electric atomizer according to the idling power consumption, the working power consumption and the atomization parameters. The atomization efficiency of the electric atomizer for aerial application of pesticides during application process is quantitatively evaluated, which provides important indicators for testing the working performance of the electric atomizer and fills in the technical gaps in the testing of traditional equipment for aerial application of pesticides.

### CROSS-REFERENCE TO RELATED APPLICATION

The present application claims priority to Chinese Patent Application No. 201910882838.0 filed on Sep. 18, 2019, entitled “Method and Device for Evaluating Atomization Efficiency of Electric Atomizer”, which is hereby incorporated by reference in its entirety.

### FIELD OF TECHNOLOGY

This application relates to the technical field of agriculture, and in particular to a method and a device for evaluating atomization efficiency of an electric atomizer.

### BACKGROUND

Aerial pesticide application of agricultural aircrafts has received considerable attention in the field of agricultural plant protection since they have the advantages of fast flying speed, high spraying operation efficiency, and strong ability to respond to sudden disasters. In recent years, agriculture aerial pesticide application technology has developed rapidly and become more widely used.

Currently, a wind-driven atomizer, typically the AU5000 product produced by Micronair Company (UK), is often adopted for applying pesticide in large manned aircraft. This atomizer has the advantages of being simple in structure, saving power and energy and the like of a centrifugal atomizer. However, in the application of pesticides, the rotation of the atomizer driven by the flying aircraft will cause great wind resistance to the aircraft and thus the aircraft's flight energy consumption as well as the cost of fuel for aircraft flight are increased.

In addition, the rotational speed of the atomizer's cage fluctuates with the fluctuation of the flight speed of the aircraft as the wind-driven atomizer is affected by the incoming wind speed, which makes the degree of atomization also vary with the flight speed of the aircraft, resulting in poor uniformity of the spray particle size. In order to solve this problem, electric atomizers for aerial application of pesticides, such as the AU7000 product produced by Micronair Company (UK), have appeared in recent years.

The atomization efficiency of an electric atomizer, which is the proportional relationship between the power consumption of the atomizer and the atomization quality of a unit volume of liquid pesticide atomized by the atomizer during the flight of the aircraft, represents a degree of electric energy consumed by the atomizer to atomize the unit volume of liquid pesticide to a certain droplet size.

The atomization efficiency of an electric atomizer is an important indicator of its working performance. However, there is no related detection method and device in the traditional technologies. Therefore, there is an urgent need for a method for evaluating the atomization efficiency of an electric atomizer.

### SUMMARY

In view of the foregoing problem, embodiments of the present application provide a method and a device for evaluating atomization efficiency of an electric atomizer.

In a first aspect, an embodiment of the present application provides a method for evaluating atomization efficiency of an electric atomizer, including:

obtaining an idling power consumption according to an idling voltage and an idling current of an electric atomizer to be measured when idling;

obtaining a working power consumption according to a working voltage and a working current of the electric atomizer to be measured when liquid pesticide flows into the electric atomizer to be measured;

obtaining atomization parameters after the electric atomizer to be measured atomizes the liquid pesticide; and

calculating the atomization efficiency of the electric atomizer to be measured according to the idling power consumption, the working power consumption and the atomization parameters.

In an embodiment, the atomization parameters include a first droplet diameter, a second droplet diameter, and a third droplet diameter, where the volume of the droplets having a diameter smaller than the first droplet diameter accounts for a first preset ratio of the volume of the atomized liquid pesticide, the volume of the droplets having a diameter smaller than the second droplet diameter accounts for a second preset ratio of the volume of the atomized liquid pesticide and the volume of the droplets having a diameter smaller than the third droplet diameter accounts for a third preset ratio of the volume of the atomized liquid pesticide.

In an embodiment, the calculating the atomization efficiency of the electric atomizer to be measured according to the idling power consumption, the working power consumption and the atomization parameters specifically includes:

obtaining a first coefficient according to the idling power consumption and the working power consumption;

obtaining an atomized particle size span of the electric atomizer to be measured according to the first droplet diameter, the second droplet diameter, and the third droplet diameter;

obtaining a second coefficient according to the second droplet diameter; and

calculating the atomization efficiency of the electric atomizer to be measured according to the first coefficient, the second coefficient and the atomized particle size span.

In an embodiment, the calculating the atomization efficiency of the electric atomizer to be measured according to the first coefficient, the second coefficient and the atomized particle size span is performed by the following calculation formula:

$$η = \frac{1}{d * p * R S} ,$$

where η represents the atomization efficiency, p represents the first coefficient, d represents the second coefficient, and RS represents the atomized particle size span.

In an embodiment, the obtaining a first coefficient according to the idling power consumption and the working power consumption is performed by the following calculation formula:

$$p = \frac{{P}_{1}}{{P}_{0}} ,$$

where p represents the first coefficient, P₁ represents the working power consumption, and P₀ represents the idling power consumption.

In an embodiment, the obtaining a second coefficient according to the second droplet diameter is performed by the following calculation formula:

d=Dv0.5₁/250,

where d represents the second coefficient, and Dv0.5₁ represents the second droplet diameter.

In an embodiment, the obtaining the atomized particle size span of the electric atomizer to be measured according to the first droplet diameter, the second droplet diameter, and the third droplet diameter is performed by the following calculation formula:

RS=(Dv0.9₁−Dv0.1₁)/Dv0.5₁,

where RS represents the atomized particle size span, Dv0.9₁ represents the third droplet diameter, Dv0.5₁ represents the second droplet diameter, and Dv0.1₁ represents the first droplet diameter.

In a second aspect, an embodiment of the present application provides a device for evaluating atomization efficiency of an electric atomizer, including: a power supply, an atomization measurement system, a liquid pesticide supplier, and a processor, wherein the power supply is connected with an electric atomizer to be measured, the liquid pesticide supplier is connected with the electric atomizer to be measured, and the processor is respectively connected in communication with the power supply, the atomization measurement system, and the liquid pesticide supplier;

the power supply is configured to supply power to the electric atomizer to be measured;

the liquid pesticide supplier is configured to provide liquid pesticide for the electric atomizer to be measured;

the atomization measurement system is configured to measure atomization parameters of atomized liquid pesticide, and the atomized liquid pesticide is formed by passing the liquid pesticide through the electric atomizer to be measured; and

the processor is configured to obtain an idling voltage and an idling current of the electric atomizer to be measured when idling, obtain a working voltage and a working current of the electric atomizer to be measured when atomizing the liquid pesticide, and calculate the atomization efficiency of the electric atomizer to be measured according to the method for evaluating atomization efficiency of an electric atomizer provided in the first aspect.

In the method and device for evaluating atomization efficiency of an electric atomizer provided by the embodiments of the present application, the atomization efficiency of the electric atomizer for aerial application of pesticides during application process is quantitatively evaluated, which provides important indicators for testing the working performance of the electric atomizer and fills in the technical gaps in the testing of traditional equipment for aerial application of pesticides.

### BRIEF DESCRIPTION OF THE DRAWINGS

In order to more clearly illustrate technical solutions disclosed in the embodiments of the present application or the prior art, the drawings needed in the descriptions of the embodiments or the prior art will be briefly described below. Obviously, the drawings in the following description only show certain embodiments of the present application, and other drawings can be obtained according to the drawings without any creative work for those skilled in the art.

FIG. 1 is a flowchart of a method for evaluating atomization efficiency of an electric atomizer according to an embodiment of the present application;

FIG. 2 is a schematic structural diagram of a device for evaluating atomization efficiency of an electric atomizer according to an embodiment of the present application; and

FIG. 3 is an application scene diagram of a device for evaluating atomization efficiency of an electric atomizer according to an embodiment of the present application.

Reference numerals:

| | |
|---|---|
| 301 power supply | 302 atomization measurement system |
| 303 liquid pesticide supplier | 304 processor |
| 305 electric atomizer to be | 306 flow rate sensor. |
| measured | |

### DETAILED DESCRIPTION

In order to make the objects, technical solutions and advantages of the embodiments of the present application more clear, the technical solutions in the embodiments of the present application are clearly and completely described in the following with reference to the accompanying drawings in the embodiments of the present application. Obviously, the described embodiments are a part of the embodiments of the present application, and not all of the embodiments. All other embodiments obtained by a person of ordinary skill in the art based on the embodiments of the present application without any creative work belong to the scope protected by the present application.

FIG. 1 is a flowchart of a method for evaluating atomization efficiency of an electric atomizer according to an embodiment of the application. As shown in FIG. 1, the method includes:

S1, obtaining an idling power consumption according to an idling voltage and an idling current of an electric atomizer to be measured when idling;

S2, obtaining a working power consumption according to a rated working voltage and a working current of the electric atomizer to be measured when liquid pesticide flows into the electric atomizer to be measured;

S3, obtaining atomization parameters after the electric atomizer to be measured atomizes the liquid pesticide; and

S4, calculating the atomization efficiency of the electric atomizer to be measured according to the idling power consumption, the working power consumption and the atomization parameters.

The idling voltage and the idling current of the electric atomizer to be measured when idling are firstly obtained. In the embodiment of the present application, idling herein means that no liquid pesticide enters the electric atomizer to be measured. In the embodiment of the present application, the measured voltage and current of the electric atomizer to be measured at a rotational speed of 2500 rpm are referred to as the idling voltage and the idling current, respectively, and the idling power consumption of the electric atomizer to be measured is calculated based on the idling voltage and the idling current.

After the liquid pesticide flows into the electric atomizer to be measured, the working voltage and the working current of the electric atomizer to be measured are then measured when the liquid pesticide is atomized, and the working power consumption of the electric atomizer to be measured is calculated according to the working voltage and the working current of the electric atomizer to be measured.

The atomization parameters after the electric atomizer to be measured atomizes the liquid pesticide are obtained, and the atomization efficiency of the electric atomizer to be measured is calculated according to the idling power consumption, the working power consumption and the atomization parameters.

In the method for evaluating atomization efficiency of an electric atomizer provided by the embodiment of the present application, the atomization efficiency of the electric atomizer for aerial application of pesticides during application process is quantitatively evaluated, which provides important indicators for testing the working performance of the electric atomizer and fills in the technical gaps in the testing of traditional equipment for aerial application of pesticides.

On the basis of the foregoing embodiment, in an embodiment, the atomization parameters include a first droplet diameter, a second droplet diameter, and a third droplet diameter, wherein the volume of the droplets having a diameter smaller than the first droplet diameter accounts for a first preset ratio of the volume of the atomized liquid pesticide, the volume of the droplets having a diameter smaller than the second droplet diameter accounts for a second preset ratio of the volume of the atomized liquid pesticide, and the volume of the droplets having a diameter smaller than the third droplet diameter accounts for a third preset ratio of the volume of the atomized liquid pesticide.

Specifically, the atomization parameters mentioned in the embodiments of the present application include the first droplet diameter Dv0.1₁, the second droplet diameter Dv0.5₁, and the third droplet diameter Dv0.9₁. The first droplet diameter represents that the volume of droplets having a diameter smaller than the first droplet diameter among all the atomized droplets accounts for 10% of the volume of all droplets. The second droplet diameter represents that the volume of droplets having a diameter smaller than the second droplet diameter among all the atomized droplets accounts for 50% of the volume of all droplets. The third droplet diameter represents that the volume of droplets having a diameter smaller than the third droplet diameter among all the atomized droplets accounts for 90% of the volume of all droplets.

On the basis of the foregoing embodiments, in an embodiment, the calculating the atomization efficiency of the electric atomizer to be measured according to the idling power consumption, the working power consumption and the atomization parameters specifically includes:

obtaining a first coefficient according to the idling power consumption and the working power consumption;

obtaining an atomized particle size span of the electric atomizer to be measured according to the first droplet diameter, the second droplet diameter, and the third droplet diameter;

obtaining a second coefficient according to the second droplet diameter; and

calculating the atomization efficiency of the electric atomizer to be measured according to the first coefficient, the second coefficient and the atomized particle size span.

The obtaining the first coefficient according to the idling power consumption and the working power consumption is performed by the following calculation formula:

$$p = \frac{{P}_{1}}{{P}_{0}} ,$$

where p represents the first coefficient, P₁ represents the working power consumption, and P₀ represents the idling power consumption.

Then, the obtaining the atomized particle size span of the electric atomizer to be measured according to the first droplet diameter, the second droplet diameter, and the third droplet diameter is performed by the following calculation formula:

RS=(Dv0.9₁−Dv0.1₁)/Dv0.5₁,

where RS represents the atomized particle size span, Dv0.9₁ represents the third droplet diameter, Dv0.5₁ represents the second droplet diameter, and Dv0.1₁ represents the first droplet diameter.

Next, the obtaining the second coefficient according to the second droplet diameter is performed by the following calculation formula:

d=Dv0.5₁/250,

where d represents the second coefficient, and Dv0.5₁ represents the second droplet diameter.

Finally, the calculating the atomization efficiency of the electric atomizer to be measured according to the first coefficient, the second coefficient and the atomized particle size span is performed by the following calculation formula:

$$η = \frac{1}{d * p * R S} ,$$

where η represents the atomization efficiency, p represents the first coefficient, d represents the second coefficient, and RS represents the atomized particle size span.

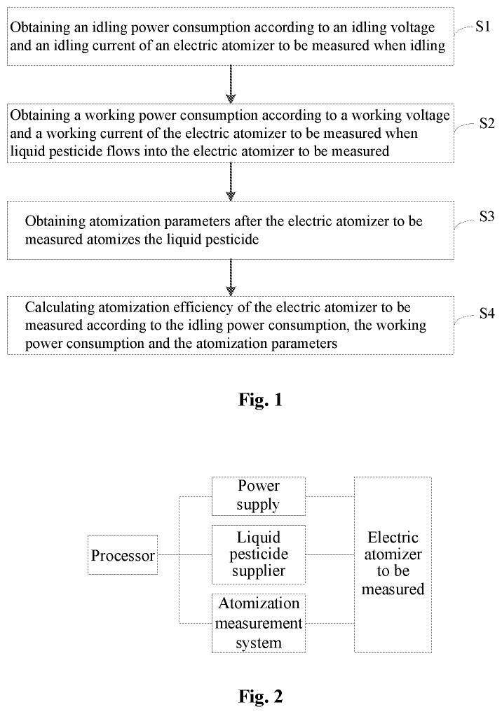

FIG. 2 is a schematic structural diagram of a device for evaluating atomization efficiency of an electric atomizer according to an embodiment of the present application. As shown in FIG. 2, the device includes:

a power supply, an atomization measurement system, a liquid pesticide supplier, and a processor, wherein the power supply is connected with the electric atomizer to be measured, the liquid pesticide supplier is connected with an electric atomizer to be measured, and the processor is respectively connected in communication with the power supply, the atomization measurement system, and the liquid pesticide supplier;

the power supply is configured to supply power to the electric atomizer to be measured;

the liquid pesticide supplier is configured to provide liquid pesticide for the electric atomizer to be measured;

the atomization measurement system is configured to measure atomization parameters of the atomized liquid pesticide, and the atomized liquid pesticide is formed by passing the liquid pesticide through the electric atomizer to be measured; and

the processor is configured to obtain an idling voltage and an idling current of the electric atomizer to be measured when idling, obtain a working voltage and a working current of the electric atomizer to be measured when atomizing the liquid pesticide, and calculate the atomization efficiency of the electric atomizer to be measured according to the method for evaluating atomization efficiency of an electric atomizer described above.

The device for evaluating atomization efficiency includes the power supply, the atomization measurement system, the liquid pesticide supplier, and the processor. When the device for evaluating the atomization efficiency is used, the electric atomizer to be measured is first powered by the power supply and idles. In the embodiment of the present application, the idling voltage and the idling current of the electric atomizer to be measured are measured when the electric atomizer to be measured has an idling speed of 2500 rpm, and the idling voltage and the idling current are transmitted to the processor.

The liquid pesticide supplier is then started, the electric atomizer to be measured is powered through the liquid pesticide supplier, the liquid pesticide is atomized by the electric atomizer to be measured, and the working voltage and the working current of the electric atomizer to be measured at this time are measured and then transmitted to the processor.

The characteristics of the liquid pesticide supplier lie in that a continuous liquid pesticide supply may be provided for the electric atomizer to be measured and the flow rate of the liquid pesticide supply may be set and kept stable.

At the same time, the atomization measurement system is configured to measure the atomization parameters of the liquid pesticide after being atomized, and transmit the atomization parameters to the processor.

The processor may be electrically connected with the power supply, the atomization measurement system, and the liquid pesticide supplier through wires or through wireless communication. The data processing method is not specifically limited in this embodiment of the present application.

After receiving the idling voltage, the idling current, the working voltage, the working current and the atomization parameters, the processor calculates the atomization efficiency of the electric atomizer to be measured according to the calculation method provided above. The specific calculation method can be referred to the above method embodiments, and is not specifically limited in the device embodiment.

In the device for evaluating atomization efficiency of an electric atomizer provided by the embodiment of the present application, the atomization efficiency of the electric atomizer for aerial application of pesticides during application process is quantitatively evaluated, which provides important indicators for testing the working performance of the electric atomizer and fills in the technical gaps in the testing of traditional equipment for aerial application of pesticides.

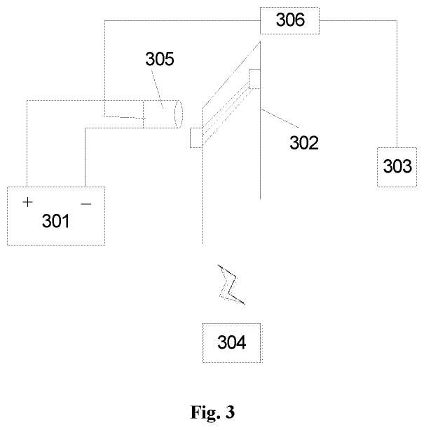

FIG. 3 is an application scene diagram of a device for evaluating atomization efficiency of an electric atomizer according to an embodiment of the present application. As shown in FIG. 3, a power supply 301 supplies power to the electric atomizer 305 to be measured. At the beginning, the electric atomizer to be measured is powered by the power supply and idles, the idling voltage and the idling current of the electric atomizer to be measured are measured when the electric atomizer to be measured has an idling speed of 2500 rpm. The liquid pesticide supplier 303 then provides liquid pesticide to the electric atomizer to be measured, and measures the working voltage and the working current of the electric atomizer to be measured during working. The liquid pesticide is atomized by the electric atomizer to be measured. Then the atomization measurement system 302 may measure the atomization parameters including the first droplet diameter, the second droplet diameter, and the third droplet diameter after the liquid pesticide is atomized.

The flow rate sensor 306 may measure the flow rate of the liquid pesticide since it is installed between the electric atomizer to be measured and the liquid pesticide supplier.

The processor 304 performs wireless communication with the power supply, the liquid pesticide supplier, and the atomization measurement system, receives the idling voltage, the idling current, the working voltage, the working current and the atomization parameters, and calculates the atomization efficiency of the electric atomizer to be measured according to the received information. The flow rate of the liquid pesticide at this time is recorded simultaneously.

The atomization efficiency of the electric atomizer to be measured at various flow rates may be calculated by changing the flow rate of the liquid pesticide, and a relationship curve showing the atomization efficiency of the electric atomizer to be measured as a function of the flow rate, i.e., an atomization efficiency curve of the electric atomizer to be measured may be obtained.

The device embodiment described above is merely illustrative, wherein the units described as separate components may or may not be physically separate, and the components displayed as units may or may not be physical units, that is, may be located at the same place, or may be distributed to multiple network units. Some or all of the modules may be selected according to actual needs to achieve the purpose of the solution of the present embodiment. Those of ordinary skill in the art can understand and implement the technical solutions described in the present application without paying creative labors.

Through the description of the embodiments above, those skilled in the art can clearly understand that the various embodiments can be implemented by means of software plus a necessary general hardware platform, and of course, by hardware. The embodiments of the present application may be embodied in the form of a software product, which may be stored in a computer readable storage media such as ROM/RAM, magnetic discs, compact discs, etc., and includes several instructions to cause a computer device (for example, personal computer, server, or network device, etc.) to perform the methods described in various embodiments or a part of the various embodiments.

Finally, it should be noted that the above embodiments are only used to explain the technical solutions of the present application, and are not limited thereto; although the present application is described in detail with reference to the foregoing embodiments, it should be understood by those skilled in the art that they can still modify the technical solutions described in the foregoing embodiments, or make equivalent substitutions to a part of the technical features; and these modifications or substitutions do not cause the essence of the corresponding technical solutions depart from the spirit and scope of the technical solutions of the various embodiments of the present application.

1. A method for evaluating atomization efficiency of an electric atomizer, comprising:
obtaining an idling power consumption according to an idling voltage and an idling current of an electric atomizer to be measured when idling;
obtaining a working power consumption according to a working voltage and a working current of the electric atomizer to be measured when liquid pesticide flows into the electric atomizer to be measured;
obtaining atomization parameters after the electric atomizer to be measured atomizes the liquid pesticide; and
calculating the atomization efficiency of the electric atomizer to be measured according to the idling power consumption, the working power consumption and the atomization parameters.

2. The method of claim 1, wherein the atomization parameters comprise a first droplet diameter, a second droplet diameter, and a third droplet diameter; the volume of the droplets having a diameter smaller than the first droplet diameter accounts for a first preset ratio of the volume of the atomized liquid pesticide, the volume of the droplets having a diameter smaller than the second droplet diameter accounts for a second preset ratio of the volume of the atomized liquid pesticide, and the volume of the droplets having a diameter smaller than the third droplet diameter accounts for a third preset ratio of the volume of the atomized liquid pesticide.

3. The method of claim 2, wherein the calculating the atomization efficiency of the electric atomizer to be measured according to the idling power consumption, the working power consumption and the atomization parameters comprises:
obtaining a first coefficient according to the idling power consumption and the working power consumption;
obtaining an atomized particle size span of the electric atomizer to be measured according to the first droplet diameter, the second droplet diameter, and the third droplet diameter;
obtaining a second coefficient according to the second droplet diameter; and
calculating the atomization efficiency of the electric atomizer to be measured according to the first coefficient, the second coefficient and the atomized particle size span.

4. The method of claim 3, wherein the calculating the atomization efficiency of the electric atomizer to be measured according to the first coefficient, the second coefficient and the atomized particle size span is performed by the following calculation formula:
$$η = \frac{1}{d * p * R S} ,$$
wherein η represents the atomization efficiency, p represents the first coefficient, d represents the second coefficient, and RS represents the atomized particle size span.

5. The method of claim 3, wherein the obtaining the first coefficient according to the idling power consumption and the working power consumption is performed by the following calculation formula:
$$p = \frac{{P}_{1}}{{P}_{0}} ,$$
wherein p represents the first coefficient, P₁ represents the working power consumption, and P₀ represents the idling power consumption.

6. The method of claim 3, wherein the obtaining the second coefficient according to the second droplet diameter is performed by the following calculation formula:
d=Dv0.5₁/250,
wherein d represents the second coefficient, and Dv0.5₁ represents the second droplet diameter.

7. The method of claim 3, wherein the obtaining the atomized particle size span of the electric atomizer to be measured according to the first droplet diameter, the second droplet diameter, and the third droplet diameter is performed by the following calculation formula:
RS=(Dv0.9₁−Dv0.1₁)/Dv0.5₁,
wherein RS represents the atomized particle size span, Dv0.9₁ represents the third droplet diameter, Dv0.5₁ represents the second droplet diameter, and Dv0.1₁ represents the first droplet diameter.

8. A device for evaluating atomization efficiency of an electric atomizer, comprising a power supply, an atomization measurement system, a liquid pesticide supplier, and a processor, wherein the power supply is connected with an electric atomizer to be measured, the liquid pesticide supplier is connected with the electric atomizer to be measured, and the processor is respectively connected in communication with the power supply, the atomization measurement system, and the liquid pesticide supplier;
the power supply is configured to supply power to the electric atomizer to be measured;
the liquid pesticide supplier is configured to provide liquid pesticide for the electric atomizer to be measured;
the atomization measurement system is configured to measure atomization parameters of atomized liquid pesticide, and the atomized liquid pesticide is formed by passing the liquid pesticide through the electric atomizer to be measured; and
the processor is configured to obtain an idling voltage and an idling current of the electric atomizer to be measured when idling, obtain a working voltage and a working current of the electric atomizer to be measured when atomizing the liquid pesticide, and calculate the atomization efficiency of the electric atomizer to be measured according to the method for evaluating atomization efficiency of an electric atomizer according to claim 1.

9. The device of claim 8, further comprising a flow rate sensor located between the liquid pesticide supplier and the electric atomizer to be measured and configured to measure a flow rate of the liquid pesticide.

10. The device of claim 9, wherein the device is also configured to measure the atomization efficiency of the electric atomizer to be measured at various flow rates of the liquid pesticide, and obtain an atomization efficiency curve of the electric atomizer to be measured.

11. A device for evaluating atomization efficiency of an electric atomizer, comprising a power supply, an atomization measurement system, a liquid pesticide supplier, and a processor, wherein the power supply is connected with an electric atomizer to be measured, the liquid pesticide supplier is connected with the electric atomizer to be measured, and the processor is respectively connected in communication with the power supply, the atomization measurement system, and the liquid pesticide supplier;
the power supply is configured to supply power to the electric atomizer to be measured;
the liquid pesticide supplier is configured to provide liquid pesticide for the electric atomizer to be measured;
the atomization measurement system is configured to measure atomization parameters of atomized liquid pesticide, and the atomized liquid pesticide is formed by passing the liquid pesticide through the electric atomizer to be measured; and
the processor is configured to obtain an idling voltage and an idling current of the electric atomizer to be measured when idling, obtain a working voltage and a working current of the electric atomizer to be measured when atomizing the liquid pesticide, and calculate the atomization efficiency of the electric atomizer to be measured according to the method for evaluating atomization efficiency of an electric atomizer according to claim 2.

12. A device for evaluating atomization efficiency of an electric atomizer, comprising a power supply, an atomization measurement system, a liquid pesticide supplier, and a processor, wherein the power supply is connected with an electric atomizer to be measured, the liquid pesticide supplier is connected with the electric atomizer to be measured, and the processor is respectively connected in communication with the power supply, the atomization measurement system, and the liquid pesticide supplier;
the power supply is configured to supply power to the electric atomizer to be measured;
the liquid pesticide supplier is configured to provide liquid pesticide for the electric atomizer to be measured;
the atomization measurement system is configured to measure atomization parameters of atomized liquid pesticide, and the atomized liquid pesticide is formed by passing the liquid pesticide through the electric atomizer to be measured; and
the processor is configured to obtain an idling voltage and an idling current of the electric atomizer to be measured when idling, obtain a working voltage and a working current of the electric atomizer to be measured when atomizing the liquid pesticide, and calculate the atomization efficiency of the electric atomizer to be measured according to the method for evaluating atomization efficiency of an electric atomizer according to claim 3.

13. A device for evaluating atomization efficiency of an electric atomizer, comprising a power supply, an atomization measurement system, a liquid pesticide supplier, and a processor, wherein the power supply is connected with an electric atomizer to be measured, the liquid pesticide supplier is connected with the electric atomizer to be measured, and the processor is respectively connected in communication with the power supply, the atomization measurement system, and the liquid pesticide supplier;
the power supply is configured to supply power to the electric atomizer to be measured;
the liquid pesticide supplier is configured to provide liquid pesticide for the electric atomizer to be measured;
the atomization measurement system is configured to measure atomization parameters of atomized liquid pesticide, and the atomized liquid pesticide is formed by passing the liquid pesticide through the electric atomizer to be measured; and
the processor is configured to obtain an idling voltage and an idling current of the electric atomizer to be measured when idling, obtain a working voltage and a working current of the electric atomizer to be measured when atomizing the liquid pesticide, and calculate the atomization efficiency of the electric atomizer to be measured according to the method for evaluating atomization efficiency of an electric atomizer according to claim 4.

14. A device for evaluating atomization efficiency of an electric atomizer, comprising a power supply, an atomization measurement system, a liquid pesticide supplier, and a processor, wherein the power supply is connected with an electric atomizer to be measured, the liquid pesticide supplier is connected with the electric atomizer to be measured, and the processor is respectively connected in communication with the power supply, the atomization measurement system, and the liquid pesticide supplier;
the power supply is configured to supply power to the electric atomizer to be measured;
the liquid pesticide supplier is configured to provide liquid pesticide for the electric atomizer to be measured;
the atomization measurement system is configured to measure atomization parameters of atomized liquid pesticide, and the atomized liquid pesticide is formed by passing the liquid pesticide through the electric atomizer to be measured; and
the processor is configured to obtain an idling voltage and an idling current of the electric atomizer to be measured when idling, obtain a working voltage and a working current of the electric atomizer to be measured when atomizing the liquid pesticide, and calculate the atomization efficiency of the electric atomizer to be measured according to the method for evaluating atomization efficiency of an electric atomizer according to claim 5.

15. A device for evaluating atomization efficiency of an electric atomizer, comprising a power supply, an atomization measurement system, a liquid pesticide supplier, and a processor, wherein the power supply is connected with an electric atomizer to be measured, the liquid pesticide supplier is connected with the electric atomizer to be measured, and the processor is respectively connected in communication with the power supply, the atomization measurement system, and the liquid pesticide supplier;
the power supply is configured to supply power to the electric atomizer to be measured;
the liquid pesticide supplier is configured to provide liquid pesticide for the electric atomizer to be measured;
the atomization measurement system is configured to measure atomization parameters of atomized liquid pesticide, and the atomized liquid pesticide is formed by passing the liquid pesticide through the electric atomizer to be measured; and
the processor is configured to obtain an idling voltage and an idling current of the electric atomizer to be measured when idling, obtain a working voltage and a working current of the electric atomizer to be measured when atomizing the liquid pesticide, and calculate the atomization efficiency of the electric atomizer to be measured according to the method for evaluating atomization efficiency of an electric atomizer according to claim 6.

16. A device for evaluating atomization efficiency of an electric atomizer, comprising a power supply, an atomization measurement system, a liquid pesticide supplier, and a processor, wherein the power supply is connected with an electric atomizer to be measured, the liquid pesticide supplier is connected with the electric atomizer to be measured, and the processor is respectively connected in communication with the power supply, the atomization measurement system, and the liquid pesticide supplier;
the power supply is configured to supply power to the electric atomizer to be measured;
the liquid pesticide supplier is configured to provide liquid pesticide for the electric atomizer to be measured;
the atomization measurement system is configured to measure atomization parameters of atomized liquid pesticide, and the atomized liquid pesticide is formed by passing the liquid pesticide through the electric atomizer to be measured; and
the processor is configured to obtain an idling voltage and an idling current of the electric atomizer to be measured when idling, obtain a working voltage and a working current of the electric atomizer to be measured when atomizing the liquid pesticide, and calculate the atomization efficiency of the electric atomizer to be measured according to the method for evaluating atomization efficiency of an electric atomizer according to claim 7.

17. The device of claim 11, further comprising a flow rate sensor located between the liquid pesticide supplier and the electric atomizer to be measured and configured to measure a flow rate of the liquid pesticide.

18. The device of claim 12, further comprising a flow rate sensor located between the liquid pesticide supplier and the electric atomizer to be measured and configured to measure a flow rate of the liquid pesticide.

19. The device of claim 17, wherein the device is also configured to measure the atomization efficiency of the electric atomizer to be measured at various flow rates of the liquid pesticide, and obtain an atomization efficiency curve of the electric atomizer to be measured.

20. The device of claim 18, wherein the device is also configured to measure the atomization efficiency of the electric atomizer to be measured at various flow rates of the liquid pesticide, and obtain an atomization efficiency curve of the electric atomizer to be measured.
